(19) United States
(12) Patent Application Publication
(10) Pub. No.: US 2015/0194951 A1
(43) Pub. Date: Jul. 9, 2015

(54) TOGGLING A CLOCKED COMPONENT USING A SLOW CLOCK TO ADDRESS BIAS TEMPERATURE INSTABILITY AGING

(71) Applicant: Nvidia Corporation, Santa Clara, CA (US)

(72) Inventors: Roman SURGUTCHIK, Santa Clara, CA (US); Brian SMITH, Mountain View, CA (US)

(73) Assignee: Nvidia Corporation, Santa Clara, CA (US)

(21) Appl. No.: 14/147,976

(22) Filed: Jan. 6, 2014

(51) Int. Cl. H03K 5/00; G06F 1/08

(52) U.S. Cl. CPC H03K 5/00006; G06F 1/08

(57) ABSTRACT

While a clocked component is not idle, the component receives a clock signal that is at a first frequency. When the clocked component is idle, the clock signal is changed to a non-zero second frequency that is less than the first frequency. In effect, clock gating is replaced with clock slowdown.

### BACKGROUND

Power consumption is of particular concern in limited-power devices (e.g., battery-powered devices) such as laptops and notebooks, smart phones, touchscreen devices, gaming consoles, and the like. These devices are limited in size and weight and generally portable, and therefore they typically use smaller and lighter batteries of increasing but still limited capacity.

One of the most widely used and well known techniques to reduce power consumption is referred to as clock gating. In essence, with clock gating, the clock signal is not propagated to a clocked component when the component is idle (not being used). Propagation of the clock signal is controlled by a gate (the “clock gate”) coupled between the clock signal generator and the clocked component. When the clock gate is enabled, then the clock signal is prevented from reaching the clocked component. Power is conserved because, for example, elements of the clocked component no longer change state in response to the rising and/or falling edges of the clock signal.

A problem with clock gating is that it can accelerate aging of the clocked components. More specifically, it is well known that clock gating can accelerate an aging mechanism known as bias temperature instability (BTI). BTI can actually increase power consumption over time; in general, BTI can change characteristics of the component such as its threshold voltage, making it necessary to increase supply voltage with age or to provide margin for aging at any time, thus increasing leakage and active power or reducing performance if frequency needs to be clamped. Thus, while clock gating is intended to have a positive effect, over the long term it can introduce some negative effects.

BTI can also lead to increased duty cycle distortion on clock distribution networks that are gated to save power. This distortion can affect the frequency of operation of logic devices and circuits and input/output devices that have duty cycle requirements.

### SUMMARY

Embodiments according to the present disclosure replace conventional clock gating with clock slowdown—actually, extreme clock slowdown. In essence, when a clocked component is idle and conventionally would be clock gated, the component is instead supplied a clock signal that is much slower than the clock signal it receives during normal operation. In effect, by toggling the component with a slow clock signal even when the component is idle, BTI aging can be slowed.

More specifically, in one embodiment, while a clocked component is not idle, the component receives a clock signal that is at a first frequency. When the clocked component is idle (in a state in which it can be clock gated), the clock signal is changed to a non-zero second frequency that is less than the first frequency. The first frequency corresponds to the normal clock frequency supplied to the component. Thus, under circumstances in which a clocked component would conventionally be clock-gated and prevented from receiving a clock signal, the clocked component instead continues to receive a clock signal, specifically a very slow clock signal.

In one embodiment, a controller can access information that indicates whether the clocked component is idle. In response to the controller determining that the clocked component is idle, the clock signal supplied to the component is reduced to the second frequency as described above. Otherwise (while the clocked component is not idle), the clock signal is at the first frequency.

In one embodiment, a clock switch circuit is used to select the clock signal received by the clocked component from among a first clock signal having the first frequency and a second clock signal having the second frequency. The first clock signal is selected if the component is not idle; the second clock signal is selected if the component is idle. The selected clock signal is then propagated to the clocked component.

In one embodiment, if the clocked component is idle, then a frequency divider is used to divide a first clock signal having the first frequency to produce a second clock signal having the second frequency. The second clock signal is then propagated to the clocked component; otherwise (if the component is not idle), the first (undivided) clock signal is propagated to the component.

By using a slower clock in place of conventional clock gating (in which no clock signal is propagated) when a component is idle, BTI aging is slowed. Furthermore, power savings that are only incrementally lower than the power savings provided by clock gating continue to be realized.

Embodiments according to the present disclosure can be utilized at any level in the clock distribution network(s). For example, the low frequency clock signal can be inserted at the phase-locked loop (PLL) root of a clock tree or in place of engine-level clock gating, block-level clock gating, and/or leaf-level clock gating.

These and other objects and advantages of the various embodiments of the present disclosure will be recognized by those of ordinary skill in the art after reading the following detailed description of the embodiments that are illustrated in the various drawing figures.

### BRIEF DESCRIPTION OF THE DRAWINGS

The accompanying drawings, which are incorporated in and form a part of this specification and in which like numerals depict like elements, illustrate embodiments of the present disclosure and, together with the description, serve to explain the principles of the disclosure.

FIG. 1 is a block diagram of an example of a computing system capable of implementing embodiments according to the present disclosure.

FIG. 2 illustrates an abstraction of a power management system in embodiments according to the present disclosure.

FIG. 3A illustrates an example of a means for replacing clock gating with a slow clock in embodiments according to the present disclosure.

FIG. 3B illustrates another example of a means for replacing clock gating with a slow clock in embodiments according to the present disclosure.

FIG. 3C illustrates another example of a means for replacing clock gating with a slow clock in embodiments according to the present disclosure.

FIG. 4 illustrates another example of a means for replacing clock gating with a slow clock in embodiments according to the present disclosure.

FIG. 5 illustrates another example of a means for replacing clock gating with a slow clock in embodiments according to the present disclosure.

FIG. 6 is a flowchart of an example of a method for replacing clock gating with a slow clock in embodiments according to the present disclosure.

### DETAILED DESCRIPTION

Reference will now be made in detail to the various embodiments of the present disclosure, examples of which are illustrated in the accompanying drawings. While described in conjunction with these embodiments, it will be understood that they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

Some portions of the detailed descriptions that follow are presented in terms of procedures, logic blocks, processing, and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those utilizing physical manipulations of physical quantities. Usually, although not necessarily, these quantities take the form of electrical or magnetic signals capable of being stored, transferred, combined, compared, and otherwise manipulated in a computing system. It has proven convenient at times, principally for reasons of common usage, to refer to these signals as transactions, bits, values, elements, symbols, characters, samples, pixels, or the like.

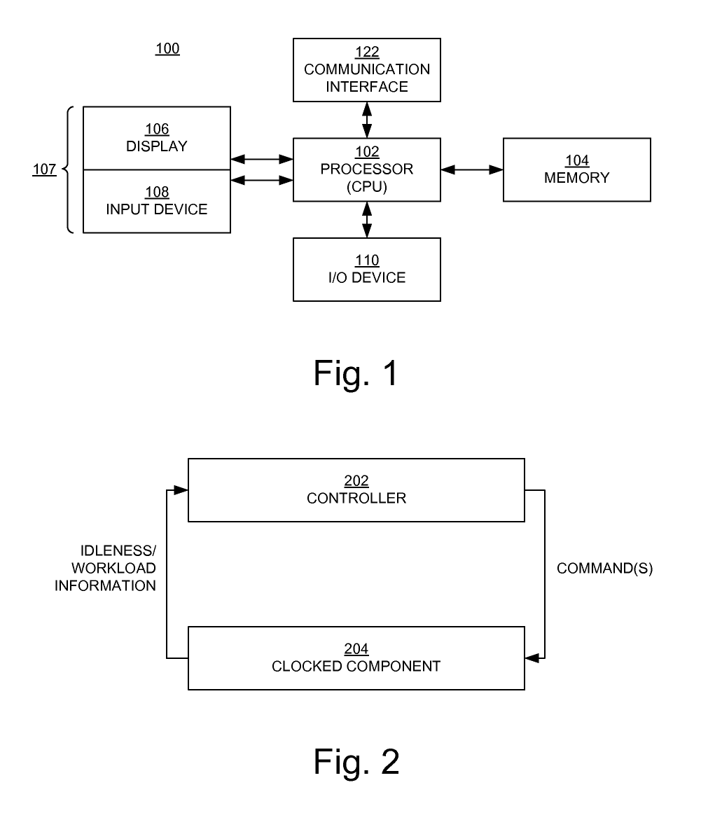

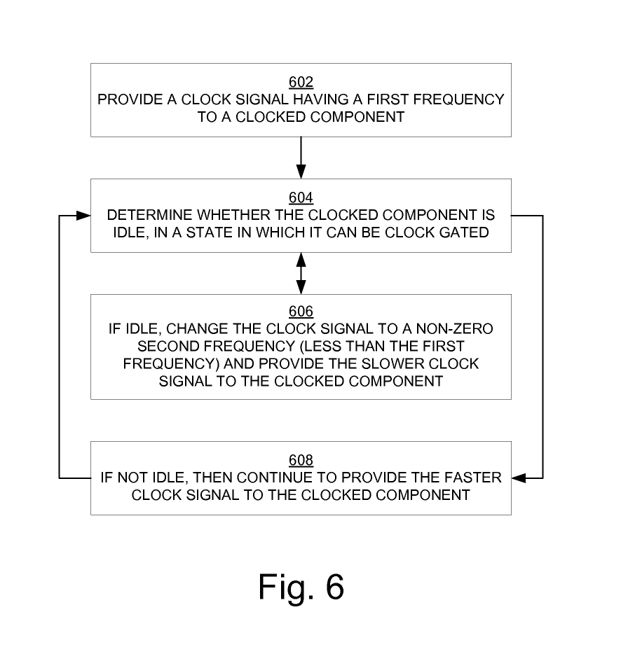

It should be borne in mind, however, that all of these and similar terms are to be associated with the appropriate physical quantities and are merely convenient labels applied to these quantities. Unless specifically stated otherwise as apparent from the following discussions, it is appreciated that throughout the present disclosure, discussions utilizing terms such as “providing,” “propagating,” “determining,” “changing,” “enabling,” “disabling,” “selecting,” “dividing,” “transitioning,” “aligning,” “receiving,” “accessing,” “controlling,” “decreasing,” “increasing,” “reducing,” or the like, refer to actions and processes (e.g., flowchart 600 of FIG. 6) of a computing system or similar electronic computing device or processor (e.g., the computing system 100 of FIG. 1). The computing system or similar electronic computing device manipulates and transforms data represented as physical (electronic) quantities within the computing system memories, registers or other such information storage, transmission or display devices.

Embodiments described herein may be discussed in the general context of computer-executable instructions residing on some form of computer-readable storage medium, such as program modules, executed by one or more computers or other devices. By way of example, and not limitation, computer-readable storage media may comprise non-transitory computer-readable storage media and communication media; non-transitory computer-readable media include all computer-readable media except for a transitory, propagating signal. Generally, program modules include routines, programs, objects, components, data structures, etc., that perform particular tasks or implement particular abstract data types. The functionality of the program modules may be combined or distributed as desired in various embodiments.

Computer storage media includes volatile and nonvolatile, removable and non-removable media implemented in any method or technology for storage of information such as computer-readable instructions, data structures, program modules or other data. Computer storage media includes, but is not limited to, random access memory (RAM), read only memory (ROM), electrically erasable programmable ROM (EEPROM), flash memory or other memory technology, compact disk ROM (CD-ROM), digital versatile disks (DVDs) or other optical storage, magnetic cassettes, magnetic tape, magnetic disk storage or other magnetic storage devices, or any other medium that can be used to store the desired information and that can accessed to retrieve that information.

Communication media can embody computer-executable instructions, data structures, and program modules, and includes any information delivery media. By way of example, and not limitation, communication media includes wired media such as a wired network or direct-wired connection, and wireless media such as acoustic, radio frequency (RF), infrared, and other wireless media. Combinations of any of the above can also be included within the scope of computer-readable media.

FIG. 1 is a block diagram of an example of a computing system 100 capable of implementing embodiments according to the present disclosure. The computing system 100 broadly represents any single or multi-processor computing device or system capable of executing computer-readable instructions. Examples of a computing system 100 include, without limitation, a laptop, tablet, or handheld computer. The computing system 100 may also be a type of computing device such as a cell phone, smart phone, media player, camera, gaming console, or the like. The computing system 100 may be powered by a battery and/or by being plugged into an electrical outlet. Depending on the implementation, the computing system 100 may not include all of the elements shown in FIG. 1, and/or it may include elements in addition to those shown in FIG. 1.

In its most basic configuration, the computing system 100 may include at least one processor 102 (CPU) and at least one memory 104. The processor 102 generally represents any type or form of processing unit capable of processing data or interpreting and executing instructions. In certain embodiments, the processor 102 may receive instructions from a software application or module. These instructions may cause the processor 102 to perform the functions of one or more of the example embodiments described and/or illustrated herein.

The memory 104 generally represents any type or form of volatile or non-volatile storage device or medium capable of storing data and/or other computer-readable instructions. In certain embodiments the computing system 100 may include both a volatile memory unit (such as, for example, the memory 104) and a non-volatile storage device (not shown).

The computing system 100 also includes a display device 106 that is operatively coupled to the processor 102. The display device 106 is generally configured to display a graphical user interface (GUI) that provides an easy to use interface between a user and the computing system.

The computing system 100 also includes an input device 108 that is operatively coupled to the processor 102. The input device 108 may include a touch sensing device (a touch screen) configured to receive input from a user's touch and to send this information to the processor 102. The processor 102 interprets the touches in accordance with its programming.

An input device 108 may be integrated with the display device 106 or they may be separate components. In the illustrated embodiment, the input device 108 is a touch screen that is positioned over or in front of the display device 106. The input device 108 and display device 106 may be collectively referred to herein as a touch screen display 107.

The communication interface 122 of FIG. 1 broadly represents any type or form of communication device or adapter capable of facilitating communication between the example computing system 100 and one or more additional devices. For example, the communication interface 122 may facilitate communication between the computing system 100 and a private or public network including additional computing systems. Examples of a communication interface 122 include, without limitation, a wired network interface (such as a network interface card), a wireless network interface (such as a wireless network interface card), a modem, and any other suitable interface. In one embodiment, the communication interface 122 provides a direct connection to a remote server via a direct link to a network, such as the Internet. The communication interface 122 may also indirectly provide such a connection through any other suitable connection. The communication interface 122 may also represent a host adapter configured to facilitate communication between the computing system 100 and one or more additional network or storage devices via an external bus or communications channel.

As illustrated in FIG. 1, the computing system 100 may also include at least one input/output (I/O) device 110. The I/O device 110 generally represents any type or form of input device capable of providing/receiving input or output, either computer- or human-generated, to/from the computing system 100. Examples of an I/O device 110 include, without limitation, a keyboard, a pointing or cursor control device (e.g., a mouse), a speech recognition device, or any other input device.

Many other devices or subsystems may be connected to computing system 100. Conversely, all of the components and devices illustrated in FIG. 1 need not be present to practice the embodiments described herein. The devices and subsystems referenced above may also be interconnected in different ways from that shown in FIG. 1. The computing system 100 may also employ any number of software, firmware, and/or hardware configurations. For example, the example embodiments disclosed herein may be encoded as a computer program (also referred to as computer software, software applications, computer-readable instructions, or computer control logic) on a computer-readable medium.

The computer-readable medium containing the computer program may be loaded into the computing system 100. All or a portion of the computer program stored on the computer-readable medium may then be stored in the memory 104. When executed by the processor 102, a computer program loaded into the computing system 100 may cause the processor 102 to perform and/or be a means for performing the functions of the example embodiments described and/or illustrated herein. Additionally or alternatively, the example embodiments described and/or illustrated herein may be implemented in firmware and/or hardware.

Embodiments according to the present disclosure replace clock gating with clock slowdown—actually, extreme clock slowdown. In essence, when a clocked component is idle and conventionally would be clock gated, the component is instead supplied a clock signal that is much slower than the clock signal it receives during normal operation. The discussion below pertains to systems that conventionally use clock gating to reduce power (versus functional clock gating where circuit operation depends on the gating of clocks for correct operation).

FIG. 2 is a block diagram illustrating an abstraction of a power management system implemented by the computing system 100 (FIG. 1) in an embodiment according to the present disclosure. In the example of FIG. 2, a controller 202 receives workload information from a clocked component 204. A clocked component is, generally speaking, a component that receives a clock signal. A clocked component may be a relatively simple functional unit or module, such as a latch or flip-flop, within a more complex device such as a chip or board, it may be the more complex device itself, or it may be something in-between. Thus, the computing system 100 may include many such clocked components. The clocked components can be utilized at any level in a clock distribution network or networks in the computing system 100: at the phase-locked loop (PLL) root of a clock tree, the engine level, the block level, and/or the leaf level, for example. The computing system 100 includes logic (not shown) that is not clock gated; that logic can decide when to enable/disable clock gating.

The controller 204 can access information (e.g., workload information and/or idleness information) that indicates whether or not the clocked component 204 is idle. Based on the workload/idleness information, the controller 202 can issue a command or commands that control the frequency of the clock signal received by the clocked component 204, as will be presented below in more detail.

The term “idle” is used herein to mean that the clocked component 204 is in a state in which it would conventionally be clock gated. In other words, as will be seen, in embodiments according to the present disclosure, the clocked component 204 will continue to receive a clock signal when, conventionally, it would be clock gated; consequently, the clocked component will change state (toggle) in response to the rising and/or falling edges of the clock signal. However, while the clocked component is being toggled in response to the slow clock signal, the component is not receiving or acting on a data signal, and/or is not outputting useful data, and in that sense is idle.

The controller 202 may be implemented on or by the processor 102 of FIG. 1, or it may be implemented outside of the processor 102. The clocked component 204 may be a part of the processor 102. On the other hand, the clocked component 204 may be a part of another device or subsystem coupled to the processor 102. As mentioned above, the computing system 100 includes logic that can monitor inputs to and the internal state of a clocked component and can decide when to enable/disable clock gating of that component; that logic may be implemented as part of the processor 102, or outside of the processor 102.

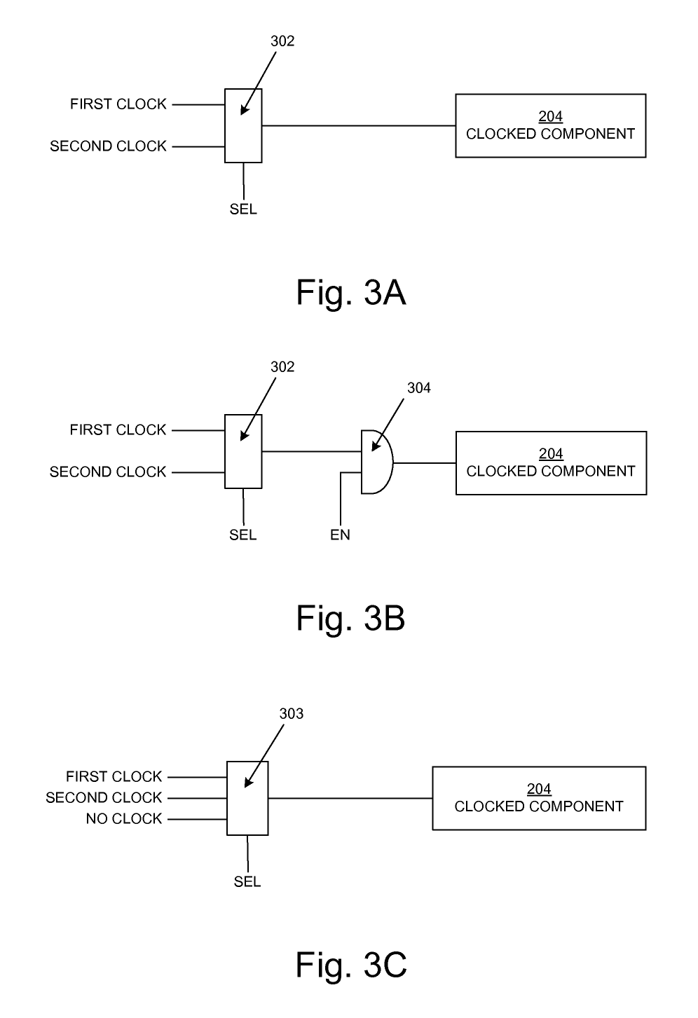

FIG. 3A illustrates an example of a means for replacing clock gating with a slow clock in embodiments according to the present disclosure. In the example of FIG. 3A, a glitchless clock switch circuit 302 (such as, but not limited to, a glitchless two-to-one clock multiplexer) receives at least two clock signals: a first clock signal having a first frequency, and a second clock signal having a second frequency. In general, the first frequency is greater than the second frequency; the first clock is faster than the second clock. The first frequency corresponds to the “normal” clock frequency supplied to the clocked component 204, when the component is active (in use). The first frequency may be changeable using techniques such as those known as dynamic frequency scaling. In one embodiment, the second frequency is in the range of approximately 20-50 kilohertz (kHz); however, the invention is not so limited, and frequencies less than 20 kHz and/or greater than 50 kHz (but less than the first frequency) may be used. In general, the slower clock frequency is chosen to reduce BTI aging effects without significantly increasing power consumption. In one embodiment, the second frequency is programmable and changeable, independent of the first frequency.

The clock switch circuit 302 can receive a select signal (SEL) either directly or indirectly from the controller 202 (FIG. 2). Generally speaking, the clock switch circuit 302 is used to select either the first clock signal or the second clock signal under control of the controller 202. There are many ways to switch clock frequencies. For example, a switch from one frequency to another can be accomplished by waiting until one clock is in one phase (e.g., the low phase), then keeping it in that phase until the other clock is also in the same phase (e.g. the low phase), at which point the transition from one clock to the other can be made.

With reference to FIG. 3B, in one embodiment, a clock gate 304 is coupled to the output of the clock switch circuit 302. The clock gate 304 may be, for example, an AND gate or a NAND gate. The clock gate 304 does not need to be included; as noted above, switching clock frequencies can be achieved without such a clock gate. Also, the clock gate 304 can be included in order to gate the clocked component 204 (in order to prevent the clocked component from receiving any clock signal, including the slower clock signal). If included, the clock gate 304 can receive an enable signal (EN) either directly or indirectly from the controller 202. Generally speaking, the clock gate 304 is enabled or not enabled under control of the controller 202. In an embodiment that includes the clock gate 304, the transition between the first clock signal and the second clock signal (that is, the transition from the first clock signal to the second clock signal, or the transition from the second clock signal to the first clock signal) is achieved by controlling (e.g., enabling) the clock gate 304 during the transition so that a clock signal is not propagated to the clocked component 204. For example, if the first clock signal is being propagated to the clocked component 204 and the second clock signal is to be used instead, then the clock gate 304 is controlled (e.g., enabled) so that no clock signal is propagated to the clocked component; while no clock signal is being propagated, the clock switch circuit 302 is controlled to select and output the second clock signal; and once the second clock signal has been selected, the clock gate is controlled (e.g., not enabled) so that the selected clock signal can be propagated to the clocked component.

In operation, workload information indicating whether or not the clocked component 204 is idle (in a state in which, conventionally, it can be clock gated) or not idle is accessed and monitored by the controller 202. If the clocked component 204 is not idle, then the first clock signal (the faster clock) is selected and propagated to the clocked component. If, on the other hand, the clocked component 204 is idle (in a condition that would conventionally result in the component being clock gated), then the second clock signal (the slower clock) is selected and propagated to the clocked component. Thus, even though the clocked component 204 is not being used, it continues to receive a clock signal—a slow clock signal, on the order of, though not limited to, 20-50 kHz.

FIG. 3C illustrates another example of a means for replacing clock gating with a slow clock in embodiments according to the present disclosure. In contrast to the example of FIG. 3A, the glitchless clock switch circuit 303 (such as, but not limited to, a glitchless three-to-one clock multiplexer) also can select a “no-clock” input, in addition to selecting either the slower or faster clock signal.

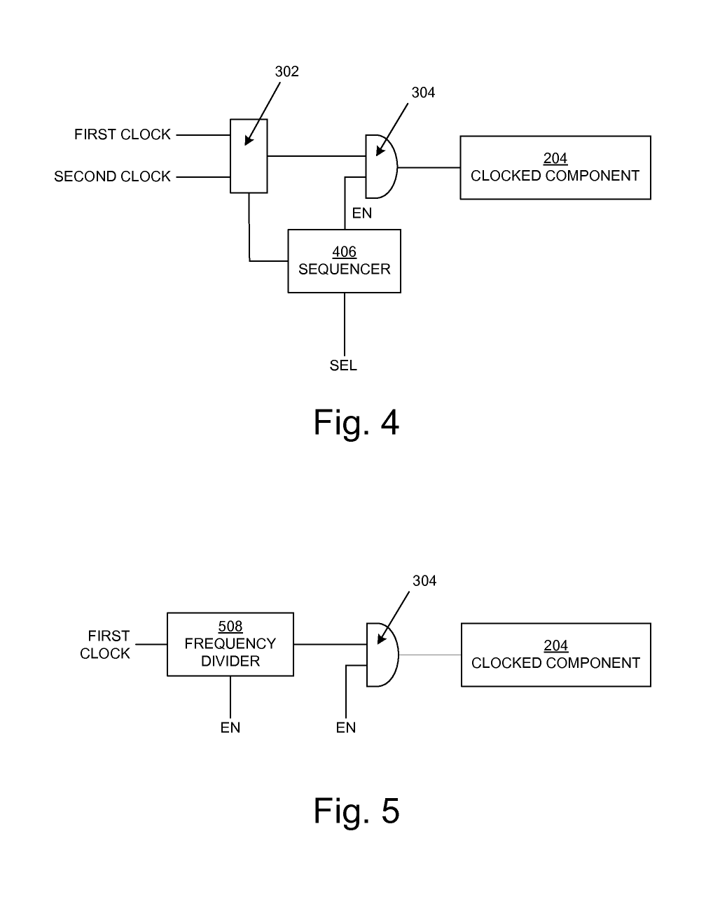

FIG. 4 illustrates another example of a means for replacing clock gating with a slow clock in embodiments according to the present disclosure. The example of FIG. 4 includes a sequencer or synchronizer 406, to transition the clock signal between the first and second frequencies. FIG. 4 represents one possible implementation of a glitchless clock switch (FIG. 3A). Although the clock gate 304 is shown in FIG. 4, a clock gate is not needed. However, the clock gate 304 can be included in order to gate the clocked component 204 (in order to prevent the clocked component from receiving any clock signal, including the slower clock signal).

FIG. 5 illustrates yet another example of a means for replacing clock gating with a slow clock in embodiments according to the present disclosure. The example of FIG. 5 functions in much the same manner as the examples of FIGS. 3A, 3B, 3C, and 4. In contrast to those examples, the example of FIG. 5 includes a frequency divider 508 in place of the clock switch circuit 302. More specifically, the first clock signal (having the higher frequency) is received at the frequency divider 508. If the clocked component 204 is not idle, then the frequency divider 508 is not enabled and the first clock signal is propagated to the clocked component. If the clocked component is idle, then the frequency divider 508 is enabled and can divide the first clock signal by a specified divisor to generate the second clock signal, which can be propagated to the clocked component 204. Although the clock gate 304 is shown in FIG. 5, a clock gate is not needed, particularly if the frequency divider 508 can switch glitchlessly between the higher and lower frequencies. However, the clock gate 304 can be included in order to gate the clocked component 204 (in order to prevent the clocked component from receiving any clock signal, including the slower clock signal).

FIG. 6 is a flowchart 600 of an example of a computer-implemented method for replacing clock gating with clock slowdown in an embodiment according to the present disclosure. The flowchart 600 can be implemented as computer-executable instructions residing on some form of computer-readable storage medium (e.g., using the computing system 100 of FIG. 1).

In block 602 of FIG. 6, a clock signal having a first frequency is provided to a clocked component.

In block 604, a determination is made as to whether the clocked component is idle (e.g., in a state in which it could conventionally be clock gated).

In block 606, in response determining that the clocked component is idle, the clock signal is changed to a non-zero second frequency that is less than the first frequency. The clocked component continues to receive a clock signal (at the second frequency) even though the component is idle.

In block 608, if the clocked component is not idle, then it continues to receive the clock signal at the first frequency.

In summary, embodiments according to the present disclosure replace conventional clock gating with clock slowdown. When a clocked component is idle and conventionally would be clock gated, the component is instead supplied a clock signal that is much slower than the clock signal it receives during normal operation. By toggling the component with a slow clock signal even when the component is idle (that is, the component changes state in response to the rising and/or falling edges of the slow clock signal even while idle), BTI aging can be slowed. Power savings that are only slightly less than the power savings provided by conventional clock gating continue to be realized, as dynamic power at the slower clock rate (e.g., 20-50 kHz) is negligible; that is, use of a slower clock as disclosed herein only slightly increases power consumption relative to conventional clock gating.

While the foregoing disclosure sets forth various embodiments using specific block diagrams, flowcharts, and examples, each block diagram component, flowchart step, operation, and/or component described and/or illustrated herein may be implemented, individually and/or collectively, using a wide range of hardware, software, or firmware (or any combination thereof) configurations. In addition, any disclosure of components contained within other components should be considered as examples because many other architectures can be implemented to achieve the same functionality.

The process parameters and sequence of steps described and/or illustrated herein are given by way of example only. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

While various embodiments have been described and/or illustrated herein in the context of fully functional computing systems, one or more of these example embodiments may be distributed as a program product in a variety of forms, regardless of the particular type of computer-readable media used to actually carry out the distribution. The embodiments disclosed herein may also be implemented using software modules that perform certain tasks. These software modules may include script, batch, or other executable files that may be stored on a computer-readable storage medium or in a computing system. These software modules may configure a computing system to perform one or more of the example embodiments disclosed herein. One or more of the software modules disclosed herein may be implemented in a cloud computing environment. Cloud computing environments may provide various services and applications via the Internet. These cloud-based services (e.g., software as a service, platform as a service, infrastructure as a service, etc.) may be accessible through a Web browser or other remote interface. Various functions described herein may be provided through a remote desktop environment or any other cloud-based computing environment.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as may be suited to the particular use contemplated.

Embodiments according to the invention are thus described. While the present disclosure has been described in particular embodiments, it should be appreciated that the invention should not be construed as limited by such embodiments, but rather construed according to the below claims.

What is claimed is:

1. A system comprising:
a clocked component operable for receiving a clock signal having a frequency; and
a controller coupled to the clocked component and having access to information that indicates whether the clocked component is idle, the controller operable for controlling the frequency of the clock signal received by the clocked component;
wherein while the clocked component is not idle the clock signal is at a first frequency; wherein further, in response to the controller determining that the clocked component is idle, the clock signal is changed to a non-zero second frequency that is less than the first frequency.

2. The system of claim 1 further comprising a clock switch circuit operable for selecting, under control of the controller, the clock signal received by the clocked component from among a first clock signal having the first frequency and a second clock signal having the second frequency.

3. The system of claim 1 further comprising a clock switch circuit operable for selecting, under control of the controller, the clock signal received by the clocked component from among: a first clock signal having the first frequency; a second clock signal having the second frequency; and a no-clock input.

4. The system of claim 1 further comprising a frequency divider operable for dividing, under control of the controller, a first clock signal having the first frequency to produce a second clock signal having the second frequency.

5. The system of claim 1 further comprising a sequencer coupled to the controller and operable for switching the clock signal between the first frequency and the second frequency.

6. The system of claim 1 wherein the second frequency is in a range of approximately 20-50 kilohertz (kHz).

7. A computing system comprising:
a memory; and
a processing unit coupled to the memory, the computing system operable for monitoring a clocked component configured to receive a clock signal having a frequency, wherein while the clocked component is not idle the clock signal is at a first frequency, and wherein further, in response to determining that the clocked component is idle and in a state in which it can be clock gated, the clock signal is changed to a non-zero second frequency that is less than the first frequency.

8. The computing system of claim 7 further comprising a clock switch circuit operable for selecting the clock signal received by the clocked component from among a first clock signal having the first frequency and a second clock signal having the second frequency.

9. The computing system of claim 7 further comprising a clock switch circuit operable for selecting, under control of the controller, the clock signal received by the clocked component from among: a first clock signal having the first frequency; a second clock signal having the second frequency; and a no-clock input.

10. The computing system of claim 7 further comprising a frequency divider operable for dividing, under control of the controller, a first clock signal having the first frequency to produce a second clock signal having the second frequency.

11. The computing system of claim 7 further comprising a sequencer coupled to the controller and operable for switching the clock signal between the first frequency and the second frequency.

12. The computing system of claim 7 wherein the second frequency is in a range of approximately 20-50 kilohertz (kHz).

13. A method comprising:
providing a clock signal having a first frequency to a clocked component;
determining whether the clocked component is idle; and
in response determining that the clocked component is idle, changing the clock signal to a non-zero second frequency that is less than the first frequency, wherein the clocked component receives the clock signal at the second frequency during an interval in which the clocked component is idle; and otherwise, while the clocked component is not idle, the clocked component receives the clock signal at the first frequency.

14. The method of claim 13 further comprising selecting, with a clock switch circuit, the clock signal received by the clocked component from among a first clock signal having the first frequency and a second clock signal having the second frequency.

15. The method of claim 13 further comprising selecting, with a clock switch circuit, the clock signal received by the clocked component from among:
a first clock signal having the first frequency; a second clock signal having the second frequency; and a no-clock input.

16. The method of claim 13 further comprising dividing a first clock signal having the first frequency to produce a second clock signal having the second frequency.

17. The method of claim 13 wherein the second frequency is in a range of approximately 20-50 kilohertz (kHz).
